(19) United States
(12) Patent Application Publication
(10) Pub. No.: US 2022/0042162 A1
(43) Pub. Date: Feb. 10, 2022

(54) INTEGRATED CIRCUIT STRUCTURES INCLUDING A METAL LAYER FORMED USING A BEAM OF LOW ENERGY ATOMS

(71) Applicant: Intel Corporation, Santa Calra, CA (US)

(72) Inventors: Elijah V. KARPOV, Portland, OR (US); Christopher J. JEZEWSKI, Portland, OR (US); Matthew V. METZ, Portland, OR (US)

(21) Appl. No.: 16/988,950

(22) Filed: Aug. 10, 2020

(51) Int. Cl. C23C 14/14; H01L 21/285; H01L 21/768; H01L 21/28; H01J 37/32; C23C 14/28

(52) U.S. Cl. CPC C23C 14/14; H01L 21/2855; H01L 21/76843; C23C 14/28; H01J 37/32715; H01J 37/3244; H01L 21/28088

(57) ABSTRACT

Systems and approaches for fabricating an integrated circuit structure including a metal layer formed using a beam of low energy atoms are described. In an example, a system for fabricating an integrated circuit structure includes a sample holder for supporting a 300 mm wafer facing down, the substrate having a feature thereon. The system also includes a source for providing a beam of low energy metal atoms to form a metal layer on the feature of the substrate. The system also includes a source of gas atoms for controlling the texture of the layer

### TECHNICAL FIELD

Embodiments of the disclosure are in the field of integrated circuit structures and, in particular, systems and approaches for fabricating an integrated circuit structure including a metal layer formed using a beam of low energy atoms.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips.

For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant. In the manufacture of integrated circuit devices, multi-gate transistors, such as tri-gate transistors, have become more prevalent as device dimensions continue to scale down. In conventional processes, tri-gate transistors are generally fabricated on either bulk silicon substrates or silicon-on-insulator substrates. In some instances, bulk silicon substrates are preferred due to their lower cost and compatibility with the existing high-yielding bulk silicon substrate infrastructure. Scaling multi-gate transistors has not been without consequence, however. As the dimensions of these fundamental building blocks of microelectronic circuitry are reduced and as the sheer number of fundamental building blocks fabricated in a given region is increased, the constraints on the semiconductor processes used to fabricate these building blocks have become overwhelming.

Integrated circuits commonly include electrically conductive microelectronic structures, which are known in the art as vias, to electrically connect metal lines or other interconnects above the vias to metal lines or other interconnects below the vias. Vias are typically formed by a lithographic process. Representatively, a photoresist layer may be spin coated over a dielectric layer, the photoresist layer may be exposed to patterned actinic radiation through a patterned mask, and then the exposed layer may be developed in order to form an opening in the photoresist layer. Next, an opening for the via may be etched in the dielectric layer by using the opening in the photoresist layer as an etch mask. This opening is referred to as a via opening. Finally, the via opening may be filled with one or more metals or other conductive materials to form the via.

Variability in conventional and state-of-the-art fabrication processes may limit the possibility to further extend them into the, e.g. 10 nm or sub-10 nm range. Consequently, fabrication of the functional components needed for future technology nodes may require the introduction of new methodologies or the integration of new technologies in current fabrication processes or in place of current fabrication processes.

### BRIEF DESCRIPTION OF THE DRAWINGS

FIG. 1 is a schematic of a process tool for forming a metal layer using a beam of low energy atoms on a source or drain region, in accordance with an embodiment of the present disclosure.

FIG. 2A illustrates a cross-sectional view of an abrupt interface between a deposited film and an underlying film, in accordance with an embodiment of the present disclosure.

FIG. 2B is a transmission electron microscope (TEM) image, in accordance with an embodiment of the present disclosure.

FIG. 2C is a schematic cross-sectional view of a structure including an underlying layer (such as a 2-dimensional 1-2 monolayer film) and a metal layer deposited thereon, in accordance with an embodiment of the present disclosure.

FIG. 2D includes a SIMS/TOFSIMS plot and Table of associated parameters, in accordance with an embodiment of the present disclosure.

FIGS. 3A and 3B include schematics of a process tool for forming a metal layer using a beam of low energy atoms on a source or drain region, in accordance with an embodiment of the present disclosure.

FIG. 4A illustrates a cross-sectional view of a semiconductor device having a metal layer formed using a beam of low energy atoms on a source or drain region, in accordance with an embodiment of the present disclosure.

FIG. 4B illustrates a cross-sectional view of another semiconductor device having a metal layer formed using a beam of low energy atoms on a raised source or drain region, in accordance with an embodiment of the present disclosure.

FIGS. 5A and 5B illustrate a plan view and a corresponding cross-sectional view, respectively, of a plurality of gate lines over a pair of semiconductor fins with intervening structures including a metal layer formed using a beam of low energy atoms on a raised source or drain region, in accordance with an embodiment of the present disclosure.

FIG. 6 illustrates a plan view and corresponding cross-sectional view of a metallization layer of an integrated circuit structure, in accordance with an embodiment of the present disclosure.

FIG. 7A illustrates a cross-sectional view of a non-planar semiconductor device having a metal layer formed using a beam of low energy atoms as a work-function layer of a gate electrode, in accordance with an embodiment of the present disclosure.

FIG. 7B illustrates a plan view taken along the a-a′ axis of the semiconductor device of FIG. 7A, in accordance with an embodiment of the present disclosure.

FIG. 8 illustrates a computing device in accordance with one implementation of an embodiment of the disclosure.

FIG. 9 is an interposer implementing one or more embodiments of the disclosure.

### DESCRIPTION OF THE EMBODIMENTS

Systems and approaches for fabricating an integrated circuit structure including a metal layer formed using a beam of low energy atoms are described. In the following description, numerous specific details are set forth, such as specific material and process regimes, in order to provide a thorough understanding of embodiments of the present disclosure. It will be apparent to one skilled in the art that embodiments of the present disclosure may be practiced without these specific details. In other instances, well-known features, such as general process tool operations, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Embodiments described herein may be directed to front-end-of-line (FEOL) semiconductor processing and structures. FEOL is the first portion of integrated circuit (IC) fabrication where the individual devices (e.g., transistors, capacitors, resistors, etc.) are patterned in the semiconductor substrate or layer. FEOL generally covers everything up to (but not including) the deposition of metal interconnect layers. Following the last FEOL operation, the result is typically a wafer with isolated transistors (e.g., without any wires).

Embodiments described herein may be directed to back end of line (BEOL) semiconductor processing and structures. BEOL is the second portion of IC fabrication where the individual devices (e.g., transistors, capacitors, resistors, etc.) are interconnected with wiring on the wafer, e.g., the metallization layer or layers. BEOL includes contacts, insulating layers (dielectrics), metal levels, and bonding sites for chip-to-package connections. In the BEOL part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

One or more embodiments described herein are directed to methods, processes and modular designs for fabricating a metal film on 300 mm wafer.

To provide context, low level interconnect technology for semiconductor manufacturing requires smaller and smaller pitch interconnects and filling higher aspect ratio vias. Contacts are being made in to thinner and thinner materials recently to 2D materials which are 1 to a few monolayers thick. Current technology fabricates interconnects by dual damascene technology based on copper (Cu). In future nodes, a change may be implemented from dual damascene to single damascene interconnects based on Cu electroplating and then to alternative metals processes using subtractive fabrication schemes enabling smaller pitch interconnects. Methods, processes and modules to deposit these metals for interconnects and contacts onto a 300 mm wafer are currently based on physical vapor deposition by sputtering, typically using Ar, from a metal target. The metal target contains a large metal disk bonded to a backing plate.

Disadvantages of previous include that physical vapor deposition (PVD) sputtering has high energy of atoms, e.g., few to 10 eV, impinging on a wafer surface. This flux of relatively high energy atoms damages the surface to be deposited on, limits the film texture control, intermixes substrate and film material and increases deposited film resistivity. For contact technology, PVD sputtering has a high energy of atoms, few to 10 eV, impinging on underlying 2D material destroys this 2D material (e.g., MoS2, WS2) because of it disorder their crystal structure and even re-sputtering/removing 1-few monolayer film itself. PVD sputtering has limited capability to fill via and trench features. Collimation is typically used which consumes a significant amount of material and becomes expensive options for high cost metals such as Ru, Ir. PVD sputtering has a minimum pressure of about a few mTorr. This results in a metal having incorporated gas species in particular for low deposition rate process, e.g., 10e15 atoms/second/cm2 can be incorporated in the deposited film at 1 mTorr (1% sticking coefficient). At 1mTorr, oxygen (O) incorporation is 10ell atoms/sec/cm2 for about one ppm purity Ar. Impurities increase film resistivity due to electron scattering. Some metals cannot be fabricated in large area disks and bonded due to such a target reliability (e.g., brittle metals such as Ru). Some alloys cannot be deposited due to large difference in component sputtering rates or phase separation. Making a large area metal disk as well as bonding it to a backing plate is a complex and an expensive process. Often, only a small area of the target is utilized during a target lifetime. Target changes are needed and the old target needs to be recycled to recover the remaining material.

Embodiments described herein can be implemented to address one or more of the above issues. In an embodiment, a beam of low energy atoms of a metal, ˜0.1 eV, is used to deposit a film on a 300 mm wafer. A low energy beam of metal atoms does not damage the surface of the underlaying film on 300 mm wafer. In addition to a beam of metal atoms, a second beam of gas atoms such as Ar is operated simultaneously or sequentially or in alternative fashion with a beam of low energy metal atoms. The second beam removes weekly bonded metal atoms (which result in low density and high resistivity films) as well as provide additional energy to adatoms to form higher quality crystal. Such a multi-beam process can be implemented to ensure the lowest resistivity possible.

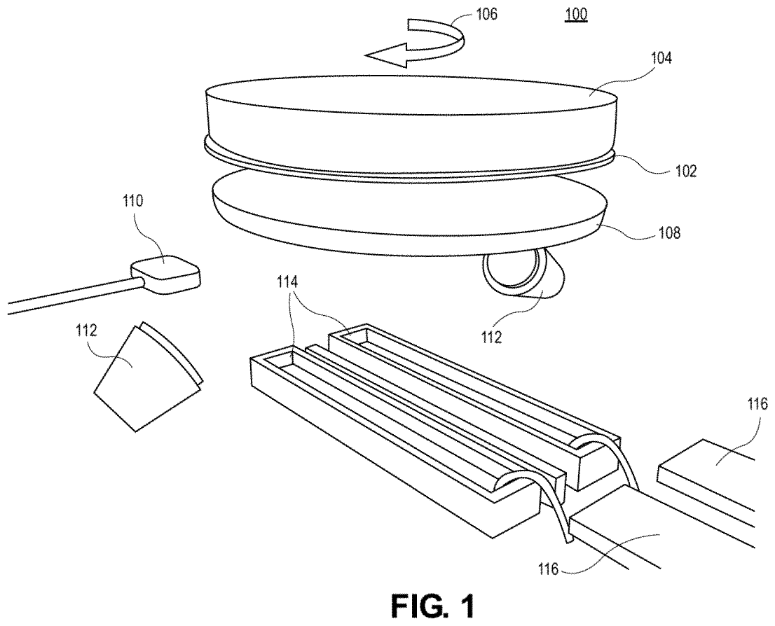

As an exemplary apparatus, FIG. 1 is a schematic of a process tool 100 for forming a metal layer using a beam of low energy atoms on a source or drain region, in accordance with an embodiment of the present disclosure.

Referring to FIG. 1, a process tool 100 accommodates a wafer 102, e.g., as supported by a heater 104 that rotates 106. The process tool 100 includes a shutter 108, a monitor 110 such as a quartz crystal monitor (QCM), variable angle ion sources 112 (e.g., Ar, Kr, Xe, N2, O2 etc.), an e-beam gun 114 such as a 180 degree e-beam gun. In one embodiment, the e-beam gun 114 is a continuous feed system based on dual linear crucibles with shutters 116, as is depicted.

The process tool 100 may be associated with lower cost of ownership. For example, the use of continuous feed source can translate to no need for large area sputter targets and target changes. Also, the process tool 100 can be implemented to provide consistent source and in situ deposition rate control.

In accordance with an embodiment of the present disclosure, the process tool 100 is a system for fabricating an integrated circuit structure that includes a sample holder for supporting a substrate, the substrate having a feature thereon. In one embodiment, the sample holder is for holding a substrate or wafer face down, e.g., a 300 mm wafer or substrate. The system also includes a source for providing a beam of low energy metal atoms to form a metal layer on the feature of the substrate. The system also includes a source of gas atoms for removing weakly held metal atoms from the feature.

In an embodiment, the source of gas atoms has an energy in the range of 50-800 eV. In one embodiment, the source of gas atoms has an energy in the range of 50-600 eV. In an embodiment, the source of gas atoms is for controlling a texture of the substrate or wafer.

In an embodiment, the source for providing the beam of low energy metal atoms and the source of gas atoms are operated simultaneously. In another embodiment, the source for providing the beam of low energy metal atoms and the source of gas atoms are operated alternately.

In one embodiment, the beam of low energy metal atoms has an energy of approximately 0.1 eV. In one embodiment the beam of low energy metal atoms has a linear shape. In one embodiment the beam of low energy metal atoms is derived from multiple locations. In one embodiment the beam of low energy metal atoms has an angle of 45 degrees normal to surface of the substrate or wafer. In one embodiment, a metal source of the metal layer is continuously supplied to the source for providing the beam of low energy metal atoms.

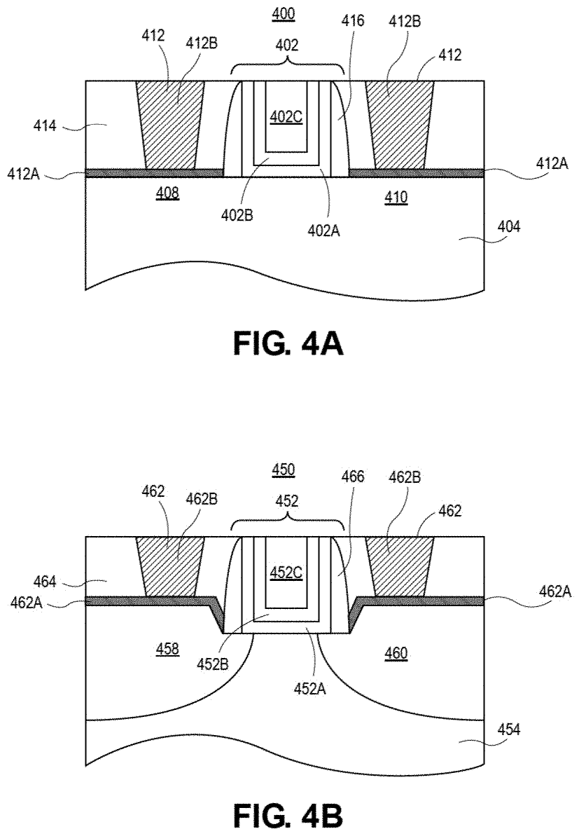

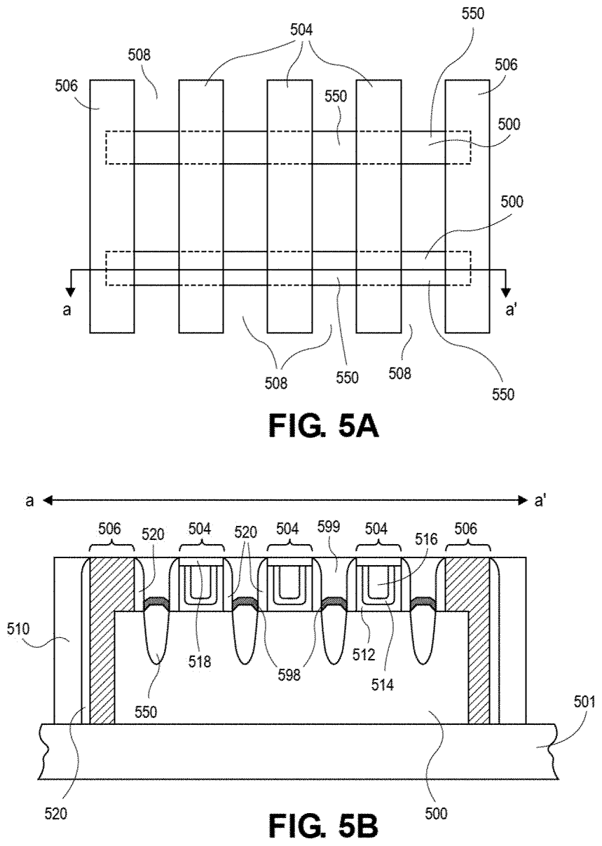

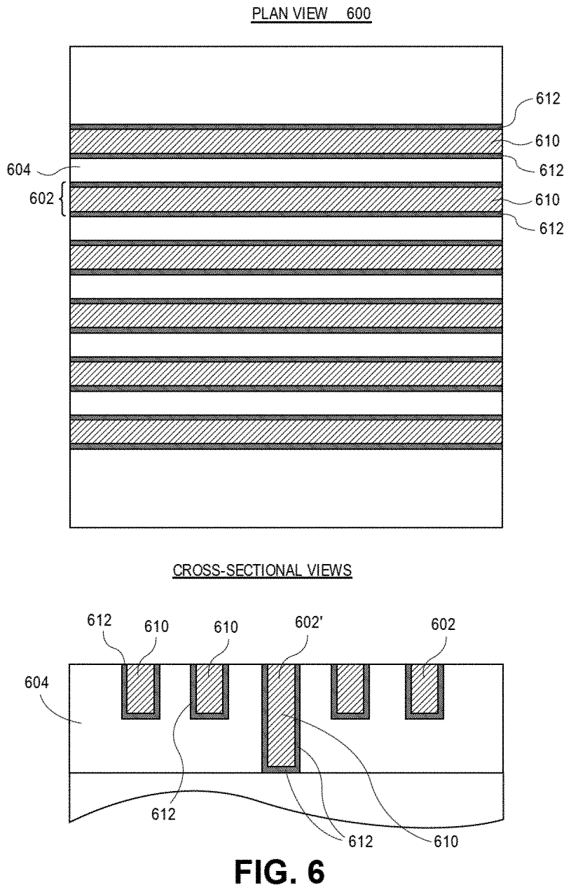

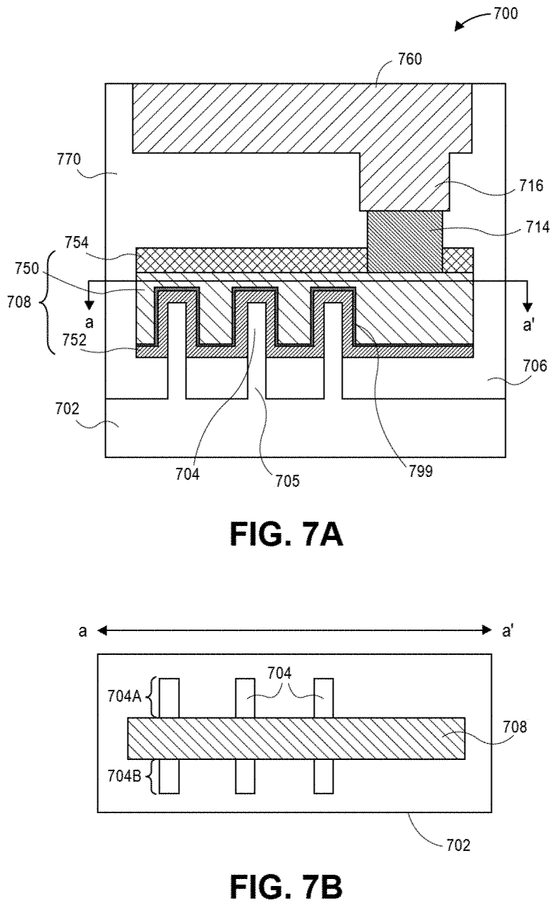

In one embodiment, the feature is a source/drain contact trench exposing a semiconductor source/drain structure, and the metal layer is a conductive contact layer for the semiconductor source/drain structure, such as described in association with FIGS. 4A, 4B, 5A and 5B. In another embodiment, the feature is a conductive line of a back end-of-line (BEOL) metallization layer, and the metal layer is barrier layer for a conductive line, such as described below in association with FIG. 6. In another embodiment, the feature is a gate trench of a semiconductor device, and the metal layer is a workfunction layer of a metal gate electrode of the semiconductor device, such as described below in association with FIGS. 7A and 7B.

In an aspect, deposition processes described herein have distinct features versus current processes used in 300 mm tools. Such a feature can be detectable in TEM. In particular, typically, an intermixing between metal deposited by a standard physical vapor deposition (PVD) process and an underlying oxide or nitride film shows a band of intermixed materials of more than four interatomic distances. In an embodiment, a process described herein does not exhibit an intermixing between layers, e.g., metal and dielectric (e.g., Si oxide or Si nitride).

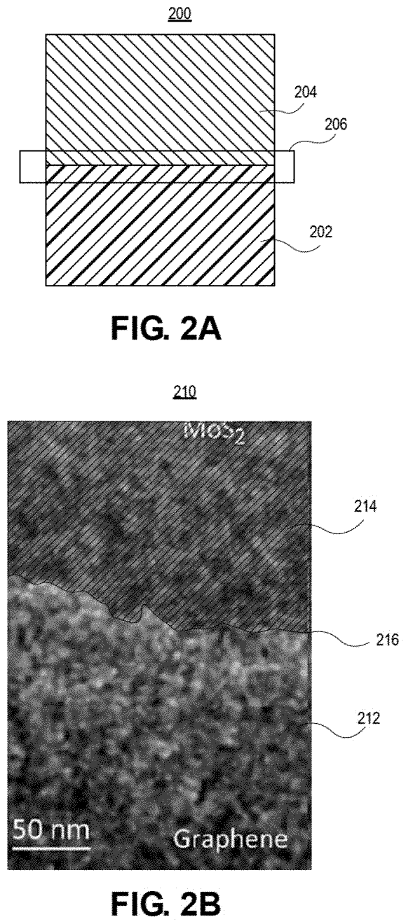

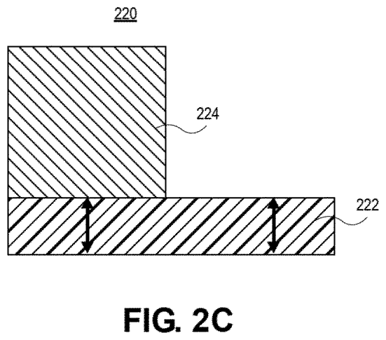

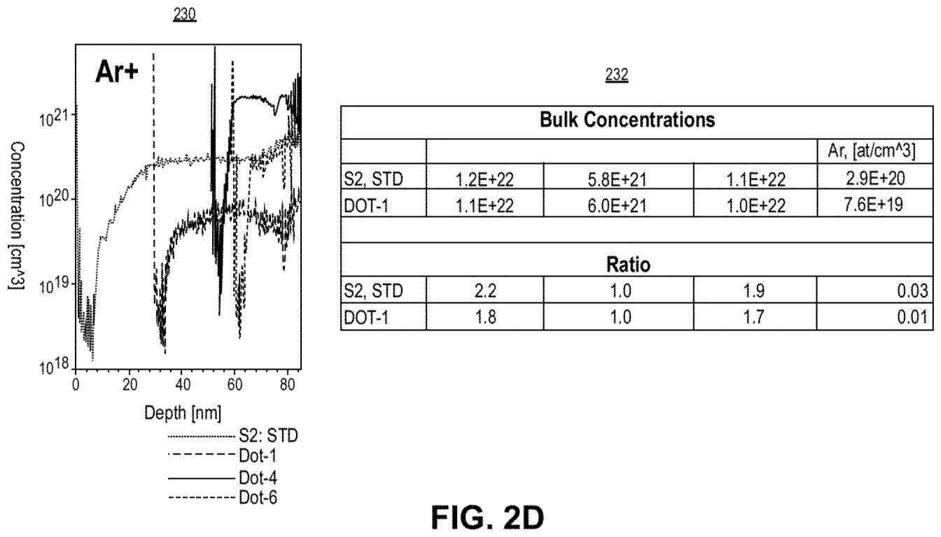

FIG. 2A illustrates a cross-sectional view 200 of an abrupt interface 206 between a deposited film and an underlying film, in accordance with an embodiment of the present disclosure. Referring to FIG. 2A, there is no intermixing (e.g., 1-2 layers in TEM) between a bottom layer 202 such as an Si oxide or silicon nitride and a metal 204. FIG. 2B is a transmission electron microscope (TEM) image 210, in accordance with an embodiment of the present disclosure. The image 210 reveals that a sharp interface 216 is possible between two materials (e.g., between graphene 212 and MoS₂ 214) when a process described herein is used.

In accordance with one or more embodiments of the present disclosure, a 300 mm process does not damage a film onto which a metal deposits. In one embodiment, it is observable that a thickness of the underlying film in an region with the metal deposited versus a region without the metal is the same or essentially the same. As an example, FIG. 2C is a schematic cross-sectional view of a structure 220 including an underlying layer 222 (such as a 2-dimensional 1-2 monolayer film) and a metal layer 224 deposited thereon, in accordance with an embodiment of the present disclosure. As depicted by the vertical arrows in the underlying layer 222, deposition approaches described herein provide the underlying layer 222 as damage-free during deposition of metal layer 224.

In another aspect, FIG. 2D includes a SIMS/TOF SIMS plot 230 and Table 232 of associated parameters, in accordance with an embodiment of the present disclosure. Referring to FIG. 2D, processes described herein in films devoid of Ar, e.g., in the whole film or at least in the first 2-10 nm of the film. Such a feature can be detected by SIMS/TOFSIMS analysis. In one embodiment, implementing a process described herein results in no Ar versus state of the art having 1-3% of Ar, as shown below. A reduced oxygen (O)% can be detected similarly. Additionally, resistivity of the metal can be measured by landing four probes on a line and measuring the sheet resistance. Thickness of the metal line times the sheet resistance provides the resistivity. Approaches described herein enable a process to significantly lower the resistivity from typical for very thin lines, e.g., less than 30 nm thick, with a resistivity of less than 8 Ohm·cm.

In accordance with one or more embodiments of the present disclosure, a process of depositing a film includes use of e-beam deposition and ion beam modules incorporated as modules in a process tool and can be operated simultaneously or e-beam deposition can be turn on first and an ion beam can be turned on later (e.g., to avoid damage of the underlying film or intermixing with an interface). High density films can be deposited in a regime where an Ar ion beam etches the metal film with an etch rate being a fraction of the deposition rate of a metal. Such a capability can enable a Deposit Etch Deposit Etch (DEDE) process to fill trenches and vias.

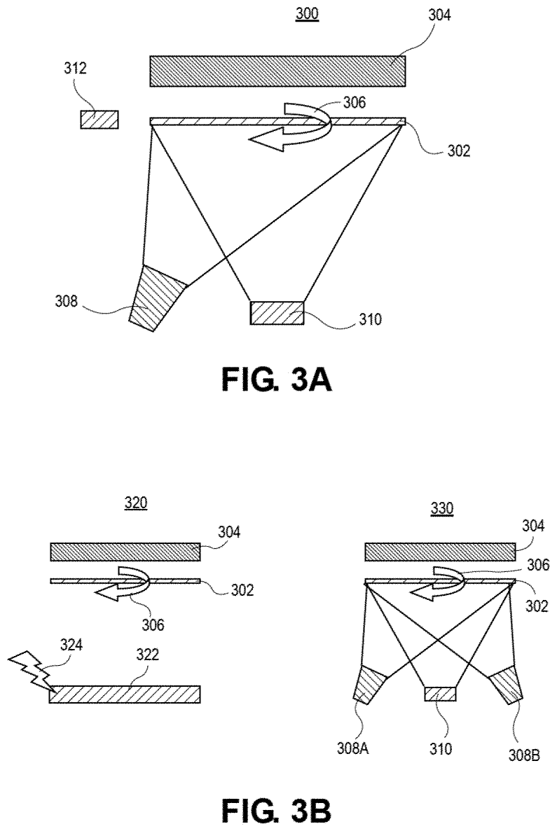

FIGS. 3A and 3B include schematics of a process tool for forming a metal layer using a beam of low energy atoms on a source or drain region, in accordance with an embodiment of the present disclosure. Referring to FIG. 3A, a system 300 includes a 300 mm wafer 302, a heater 304 that rotates 306, an ion beam 308, a single or multiple e-beam material source 310, and a thickness monitor 312. Referring to FIG. 3B, a first side view 320 depicts a 300 mm wafer 302, a heater 304 that rotates 306, a linear e-beam source 322 with continuous feed and a shutter, and an e-beam 324. A second side view 330 depicts a 300 mm wafer 302, a heater 304 that rotates 306, ion sources 308A and 308B with shutters, and an e-beam source 310.

In accordance with one or more embodiments of the present disclosure, a wafer is on top of a system and it faces down. The wafer rotates or the e-beam source or ion source rotates. An e-beam source is not typical circular pockets in a copper (Cu) chill plate but rather have a liner shape to cover a 300 mm wafer diameter or larger. Material can be constantly feeding the e-beam source to maintain the same level and avoid any “target” changes. Removable shields can accumulate material during deposition which can be recycled. Metals can include Ru, Mo, W, Cu , Rh, Ir, or Pt. In some embodiments, two linear e-beam sources are used to deposit alloys such as RuTa3, Ru3V, Rulr, RuAl, AlNi, AlRe, AlMn, AlTi, MoNb, MoTa, MoRh3, MoRh, Molr, Mo3Pt, MoPt3, or CuZn. In some embodiments, instead of Ar an ion source, N2 can be used to deposit MAX phases: V2SiN V3SiN, V4SiN3. In one embodiment, high density films are deposited in a regime when an Ar ion beam etches metals with an etch rate being a fraction of the deposition rate of a metal to enable a Deposit Etch Deposit Etch (DEDE) process, e.g., to fill trenches and vias.

In another aspect, FIG. 4A illustrates a cross-sectional view of a semiconductor device having a metal layer formed using a beam of low energy atoms on a source or drain region, in accordance with an embodiment of the present disclosure. FIG. 4B illustrates a cross-sectional view of another semiconductor device having a conductive on a raised source or drain region, in accordance with an embodiment of the present disclosure.

Referring to FIG. 4A, a semiconductor structure 400 includes a gate structure 402 above a substrate 404. The gate structure 402 includes a gate dielectric layer 402A, a work-function layer 402B, and a gate fill 402C. A source region 408 and a drain region 410 are on opposite sides of the gate structure 402. Source or drain contacts 412 are electrically connected to the source region 408 and the drain region 410, and are spaced apart of the gate structure 402 by one or both of an inter-layer dielectric layer 414 or gate dielectric spacers 416. The source region 408 and the drain region 410 are monocrystalline regions of the substrate 404. In an embodiment, the source or drain contacts 412 include a metal layer 412A formed using a beam of low energy atoms, such as described above in association with FIGS. 1, 2A-2D, 3A and 3B, and a conductive trench fill material 412B.

Referring to FIG. 4B, a semiconductor structure 450 includes a gate structure 452 above a substrate 454. The gate structure 452 includes a gate dielectric layer 452A, a work-function layer 452B, and a gate fill 452C. A source region 458 and a drain region 460 are on opposite sides of the gate structure 452. Source or drain contacts 462 are electrically connected to the source region 458 and the drain region 460, and are spaced apart of the gate structure 452 by one or both of an inter-layer dielectric layer 464 or gate dielectric spacers 466. The source region 458 and the drain region 460 are epitaxial and/or embedded material regions formed in etched-out regions of the substrate 454. As is depicted, in an embodiment, the source region 458 and the drain region 460 are raised source and drain regions. In a specific such embodiment, the raised source and drain regions are raised silicon source and drain regions or raised silicon germanium source and drain regions. In an embodiment, the source or drain contacts 462 include a metal layer 462A formed using a beam of low energy atoms, such as described above in association with FIGS. 1, 2A-2D, 3A and 3B, and a conductive trench fill material 462B.

FIGS. 5A and 5B illustrate a plan view and a corresponding cross-sectional view, respectively, of a plurality of gate lines over a pair of semiconductor fins with intervening structures including a metal layer formed using a beam of low energy atoms on a raised source or drain region, in accordance with an embodiment of the present disclosure.

Referring to FIGS. 5A and 5B, a plurality of active gate lines 504 is formed over a plurality of semiconductor fins 500 above a substrate 501. Dummy gate lines 506 are at the ends of the plurality of semiconductor fins 500. Spacings 508 between the gate lines 504/506 are locations where trench contacts may be formed as conductive contacts to source or drain regions, such as source or drain regions 550.

In an embodiment, the pattern of the plurality of gate lines 504/506 and/or the pattern of the plurality of semiconductor fins 500 is described as a grating structure. In an embodiment, the term “grating” for the plurality of gate lines 504/506 and/or the pattern of the plurality of semiconductor fins 500 is used herein to refer to a tight pitch grating structure. In one such embodiment, the tight pitch is not achievable directly through conventional lithography. For example, a pattern based on conventional lithography may first be formed, but the pitch may be halved by the use of spacer mask patterning, as is known in the art. Even further, the original pitch may be quartered by a second round of spacer mask patterning. Accordingly, the grating-like patterns described herein may have the plurality of gate lines 504/506 and/or the pattern of the plurality of semiconductor fins 500 spaced at a constant pitch and having a constant width. The pattern may be fabricated by a pitch halving or pitch quartering, or other pitch division, approach.

Referring to FIG. 5B, a dielectric layer 510 is on outer ends of the structure. Embedded source or drain structures 550 are in the semiconductor fin 500 between adjacent ones of the active gate lines 504 and between the dummy gate lines 506 and the active gate lines 504. In one embodiment, the active gate lines 504 include a gate dielectric layer 512, a work-function gate electrode portion 514 and a fill gate electrode portion 516, and, possibly, a dielectric capping layer 518. Dielectric spacers 520 line the sidewalls of the active gate lines 504 and the dummy gate lines 506. In an embodiment, a metal layer 598 formed using a beam of low energy atoms, such as described above in association with FIGS. 1, 2A-2D, 3A and 3B, is on each of the source or drain structures 550. Trench contacts 599 are between the active gate lines 504 and between the dummy gate lines 506 and the active gate lines 504. Trench contacts 599 may include a conductive liner and a conductive fill, or only a conductive fill.

With reference again to FIG. 5B, in accordance with an embodiment of the present disclosure, an integrated circuit structure includes a semiconductor fin 500 above a substrate 501, the semiconductor fin having a top and sidewalls. A gate electrode (one 504) is over the top and adjacent to the sidewalls of a portion of the semiconductor fin 500, the gate electrode 504 defining a channel region in the semiconductor fin 500. A first epitaxial semiconductor source or drain structure (first 550) is at a first end of the channel region at a first side of the gate electrode 504, the first epitaxial semiconductor 550 source or drain structure having a non-flat topography. A second epitaxial semiconductor source or drain structure (second 550) is at a second end of the channel region at a second side of the gate electrode 504, the second end opposite the first end, the second side opposite the first side, and the second epitaxial semiconductor source or drain structure (second 550) having a non-flat topography. A metal layer 598 is in direct contact with each of the first and second epitaxial semiconductor source or drain structures 550. In an embodiment, the metal layer is conformal with and hermetically sealing the non-flat topography of each of the first and second epitaxial semiconductor source or drain structures 550.

In an embodiment, the non-flat topography of each of the first and second epitaxial semiconductor source or drain structures 550 includes a raised central portion and lower side portions, a non-limiting example of which is depicted in FIG. 5B. In an embodiment, the first epitaxial semiconductor source or drain structure 550 and the second epitaxial semiconductor source or drain structure 550 both include silicon. In one such embodiment, the first epitaxial semiconductor source or drain structure 550 and the second epitaxial semiconductor source or drain structure 550 both further include germanium.

In another aspect, FIG. 6 illustrates a plan view and corresponding cross-sectional view of a metallization layer of an integrated circuit structure, in accordance with an embodiment of the present disclosure.

Referring to FIG. 6, a metallization layer 600 includes a pattern of conductive lines 602 and interlayer dielectric (ILD) lines 604. The metallization layer 600 may be patterned in a grating-like pattern with conductive lines 602 spaced at a constant pitch and having a constant width, as is depicted in FIG. 6. Although not shown, the conductive lines 602 may have interruptions (i.e., cuts or plugs) at various locations along the lines. Some of the conductive lines may be associated with underlying vias, such as line 602′ shown as an example in the cross-sectional view.

In an embodiment, the term “grating” for conductive lines 602 and ILD lines 604 is used herein to refer to a tight pitch grating structure. In one such embodiment, the tight pitch is not achievable directly through conventional lithography. For example, a pattern based on conventional lithography may first be formed, but the pitch may be halved by the use of spacer mask patterning, as is known in the art. Even further, the original pitch may be quartered by a second round of spacer mask patterning. Accordingly, the grating-like patterns described herein may have conductive lines 602 and/or ILD lines 604 spaced at a constant pitch and having a constant width. The pattern may be fabricated by a pitch halving or pitch quartering, or other pitch division, approach.

In an embodiment, the conductive lines 602 (and, possibly, underlying via structures) are composed of one or more metal or other conductive structures. The conductive lines 602 are also sometimes referred to in the art as traces, wires, lines, metal, interconnect lines or simply interconnects. In a particular embodiment, each of the conductive lines 602 includes a barrier layer 612 and a conductive fill material 610.

In an embodiment, the conductive fill material 610 is formed using a beam of low energy atoms, such as described above in association with FIGS. 1, 2A-2D, 3A and 3B. In an embodiment, the conductive fill material 610 is composed of a conductive material such as, but not limited to, Cu, Al, Ti, Zr, Hf, V, Ru, Co, Ni, Pd, Pt, W, Ag, Au or alloys thereof.

In an embodiment, ILD lines 604 are composed of or includes a layer of a dielectric or insulating material. Examples of suitable dielectric materials include, but are not limited to, oxides of silicon (e.g., silicon dioxide (SiO₂)), doped oxides of silicon, fluorinated oxides of silicon, carbon doped oxides of silicon, various low-k dielectric materials known in the art, and combinations thereof. The interlayer dielectric material may be formed by conventional techniques, such as, for example, chemical vapor deposition (CVD), physical vapor deposition (PVD), or by other deposition methods.

It is to be appreciated that the layers and materials described in association with FIG. 6 are typically formed on or above an underlying semiconductor substrate or structure, such as underlying device layer(s) of an integrated circuit. In an embodiment, an underlying semiconductor substrate represents a general workpiece object used to manufacture integrated circuits. The semiconductor substrate often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials. The semiconductor substrate, depending on the stage of manufacture, often includes transistors, integrated circuitry, and the like. The substrate may also include semiconductor materials, metals, dielectrics, dopants, and other materials commonly found in semiconductor substrates. Furthermore, although not depicted, the structure depicted in FIG. 6 may be fabricated on underlying lower level back end of line (BEOL) interconnect layers.

In another aspect, one or more embodiments described herein are directed to fabricating semiconductor devices, such as for metal oxide semiconductor (MOS) device fabrication. As an example, FIG. 7A illustrates a cross-sectional view of a non-planar semiconductor device having a metal layer formed using a beam of low energy atoms as a work-function layer of a gate electrode, in accordance with an embodiment of the present disclosure. FIG. 7B illustrates a plan view taken along the a-a′ axis of the semiconductor device of FIG. 7A, in accordance with an embodiment of the present disclosure.

Referring to FIG. 7A, a semiconductor structure or device 700 includes a non-planar active region (e.g., a fin structure including protruding fin portion 704 and sub-fin region 705) formed from substrate 702, and within isolation region 706. A gate line 708 is disposed over the protruding portions 704 of the non-planar active region as well as over a portion of the isolation region 706. As shown, gate line 708 includes a gate electrode 750/799 and a gate dielectric layer 752. In one embodiment, gate line 708 may also include a dielectric cap layer 754. A gate contact 714, and overlying gate contact via 716 are also seen from this perspective, along with an overlying metal interconnect 760, all of which are disposed in inter-layer dielectric stacks or layers 770. Also seen from the perspective of FIG. 7A, the gate contact 714 is, in one embodiment, disposed over isolation region 706, but not over the non-planar active regions.

In accordance with an embodiment of the present disclosure, the layer 799 of gate electrode 750/799 is a metal layer formed using a beam of low energy atoms, such as described above in association with FIGS. 1, 2A-2D, 3A and 3B. In one embodiment, the metal layer 799 formed using a beam of low energy atoms is in a gate trench, and is on or above gate dielectric layer 752. In one such embodiment, the metal layer 799 formed using a beam of low energy atoms is a work-function layer of a metal gate electrode of a transistor 700 of the integrated circuit structure. In a particular embodiment, the transistor 700 is an N-type (NMOS) transistor or is a P-type (PMOS) transistor.

Referring to FIG. 7B, the gate line 708 is shown as disposed over the protruding fin portions 704. Source and drain regions 704A and 704B of the protruding fin portions 704 can be seen from this perspective. In one embodiment, the source and drain regions 704A and 704B are doped portions of original material of the protruding fin portions 704. In another embodiment, the material of the protruding fin portions 704 is removed and replaced with another semiconductor material, e.g., by epitaxial deposition. In either case, the source and drain regions 704A and 704B may extend below the height of dielectric layer 752, i.e., into the sub-fin region 705.

In an embodiment, the semiconductor structure or device 700 is a non-planar device such as, but not limited to, a fin-FET or a tri-gate device. In such an embodiment, a corresponding semiconducting channel region is composed of or is formed in a three-dimensional body. In one such embodiment, the gate electrode and gate electrode materials of gate lines 708 surround at least a top surface and a pair of sidewalls of the three-dimensional body.

Substrate 702 may be composed of a semiconductor material that can withstand a manufacturing process and in which charge can migrate. In an embodiment, substrate 702 is a bulk substrate composed of a crystalline silicon, silicon/germanium or germanium layer doped with a charge carrier, such as but not limited to phosphorus, arsenic, antimony, boron, gallium or a combination thereof, to form active region 704. In one embodiment, the concentration of silicon atoms in bulk substrate 702 is greater than 97%. In another embodiment, bulk substrate 702 is composed of an epitaxial layer grown atop a distinct crystalline substrate, e.g. a silicon epitaxial layer grown atop a boron-doped bulk silicon mono-crystalline substrate. Bulk substrate 702 may alternatively be composed of a group III-V material. In an embodiment, bulk substrate 702 is composed of a group III-V material such as, but not limited to, gallium nitride, gallium phosphide, gallium arsenide, indium phosphide, indium antimonide, indium gallium arsenide, aluminum gallium arsenide, indium gallium phosphide, or a combination thereof. In one embodiment, bulk substrate 702 is composed of a group III-V material and the charge-carrier dopant impurity atoms are ones such as, but not limited to, magnesium, beryllium, zinc, carbon, silicon, germanium, oxygen, sulfur, selenium or tellurium.

Isolation region 706 may be composed of a material suitable to ultimately electrically isolate, or contribute to the isolation of, portions of a permanent gate structure from an underlying bulk substrate or isolate active regions formed within an underlying bulk substrate, such as isolating fin active regions. For example, in one embodiment, the isolation region 706 is composed of a dielectric material such as, but not limited to, silicon dioxide, silicon oxy-nitride, silicon nitride, or carbon-doped silicon nitride.

In an embodiment, the gate dielectric layer 752 is composed of a high-k material. For example, in one embodiment, the gate dielectric layer 752 is composed of a material such as, but not limited to, hafnium oxide, hafnium oxy-nitride, hafnium silicate, lanthanum oxide, zirconium oxide, zirconium silicate, tantalum oxide, barium strontium titanate, barium titanate, strontium titanate, yttrium oxide, aluminum oxide, lead scandium tantalum oxide, lead zinc niobate, or a combination thereof. Furthermore, a portion of gate dielectric layer 752 may include a layer of native oxide formed from the top few layers of the substrate 702. In an embodiment, the gate dielectric layer is composed of a top high-k portion and a lower portion composed of an oxide of a semiconductor material. In one embodiment, the gate dielectric layer 752 is composed of a top portion of hafnium oxide and a bottom portion of silicon dioxide or silicon oxy-nitride.

In an embodiment, layer 750 of the gate electrode 750/799 is composed of a non-work-function-setting conductive fill material formed above the metal layer 799 formed using a beam of low energy atoms. In one such embodiment, the conductive fill material 750 includes a material such as but not limited to, tungsten (W), aluminum (Al), or copper (Cu). In one embodiment, one or more conductive barrier layers (such as titanium nitride or tantalum nitride) is between layers 750 and 799 of the gate electrode. In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the disclosure, the gate electrode may consist of a combination of U-shaped structures and planar, non-U-shaped structures. For example, the gate electrode may consist of one or more U-shaped metal layers formed atop one or more planar, non-U-shaped layers.

In an embodiment, the dielectric cap layer 754 and/or dielectric spacers associated with the gate electrode stacks may be composed of a material suitable to ultimately electrically isolate, or contribute to the isolation of, a permanent gate structure from adjacent or overlying conductive contacts, such as self-aligned contacts. For example, in one embodiment, the dielectric cap layer 754 and/or dielectric spacers are composed of a dielectric material such as, but not limited to, silicon dioxide, silicon oxy-nitride, silicon nitride, or carbon-doped silicon nitride.

Gate contact 714, overlying gate contact via 716, and/or overlying metal interconnect 760 may be composed of a conductive material. In an embodiment, one or more of the contacts, interconnects or vias are composed of a metal species. The metal species may be a pure metal, such as tungsten, nickel, or cobalt, or may be an alloy such as a metal-metal alloy or a metal-semiconductor alloy (e.g., such as a silicide material). In a particular embodiment, one or more of gate contact 714, overlying gate contact via 716, or overlying metal interconnect 760 includes a barrier layer and a conductive fill material. In one such embodiment, the barrier layer is a metal layer formed using a beam of low energy atoms, such as described above. In an embodiment, the conductive fill material is composed of a conductive material such as, but not limited to, Cu, Al, Ti, Zr, Hf, V, Ru, Co, Ni, Pd, Pt, W, Ag, Au or alloys thereof.

In an embodiment (although not shown), providing structure 700 involves formation of a contact pattern which is essentially perfectly aligned to an existing gate pattern while eliminating the use of a lithographic step with exceedingly tight registration budget. In one such embodiment, this approach enables the use of intrinsically highly selective wet etching (e.g., versus conventionally implemented dry or plasma etching) to generate contact openings. In an embodiment, a contact pattern is formed by utilizing an existing gate pattern in combination with a contact plug lithography operation. In one such embodiment, the approach enables elimination of the need for an otherwise critical lithography operation to generate a contact pattern, as used in conventional approaches. In an embodiment, a trench contact grid is not separately patterned, but is rather formed between poly (gate) lines. For example, in one such embodiment, a trench contact grid is formed subsequent to gate grating patterning but prior to gate grating cuts.

Furthermore, the gate stack structure 708 may be fabricated by a replacement gate process. In such a scheme, dummy gate material such as polysilicon or silicon nitride pillar material, may be removed and replaced with permanent gate electrode material. In one such embodiment, a permanent gate dielectric layer is also formed in this process, as opposed to being carried through from earlier processing. In an embodiment, dummy gates are removed by a dry etch or wet etch process. In one embodiment, dummy gates are composed of polycrystalline silicon or amorphous silicon and are removed with a dry etch process including use of SF₆. In another embodiment, dummy gates are composed of polycrystalline silicon or amorphous silicon and are removed with a wet etch process including use of aqueous NH₄OH or tetramethylammonium hydroxide. In one embodiment, dummy gates are composed of silicon nitride and are removed with a wet etch including aqueous phosphoric acid.

In an embodiment, one or more approaches described herein contemplate essentially a dummy and replacement gate process in combination with a dummy and replacement contact process to arrive at structure 700. In one such embodiment, the replacement contact process is performed after the replacement gate process to allow high temperature anneal of at least a portion of the permanent gate stack. For example, in a specific such embodiment, an anneal of at least a portion of the permanent gate structures, e.g., after a gate dielectric layer is formed, is performed at a temperature greater than approximately 600 degrees Celsius. The anneal is performed prior to formation of the permanent contacts.

Referring again to FIG. 7A, the arrangement of semiconductor structure or device 700 places the gate contact over isolation regions. Such an arrangement may be viewed as inefficient use of layout space in certain applications. In another embodiment, however, a semiconductor device has contact structures that contact portions of a gate electrode formed over an active region. In general, prior to (e.g., in addition to) forming a gate contact structure (such as a via) over an active portion of a gate and in a same layer as a trench contact via, one or more embodiments of the present disclosure include first using a gate aligned trench contact process. Such a process may be implemented to form trench contact structures for semiconductor structure fabrication, e.g., for integrated circuit fabrication. In an embodiment, a trench contact pattern is formed as aligned to an existing gate pattern. By contrast, conventional approaches typically involve an additional lithography process with tight registration of a lithographic contact pattern to an existing gate pattern in combination with selective contact etches. For example, a conventional process may include patterning of a poly (gate) grid with separate patterning of contact features.

In a particular embodiment, each of the trench contacts includes a barrier layer and a conductive fill material, or only a conductive fill material. In an embodiment, the trench contacts are formed on a metal layer formed using a beam of low energy atoms formed on the source or drain structures. In an embodiment, the conductive fill material is composed of a conductive material such as, but not limited to, Cu, Al, Ti, Zr, Hf, V, Ru, Co, Ni, Pd, Pt, W, Ag, Au or alloys thereof.

It is to be appreciated that not all aspects of the processes described above need be practiced to fall within the spirit and scope of embodiments of the present disclosure. For example, in one embodiment, dummy gates need not ever be formed prior to fabricating gate contacts over active portions of the gate stacks. The gate stacks described above may actually be permanent gate stacks as initially formed. Also, the processes described herein may be used to fabricate one or a plurality of semiconductor devices. The semiconductor devices may be transistors or like devices. For example, in an embodiment, the semiconductor devices are a metal-oxide semiconductor (MOS) transistors for logic or memory, or are bipolar transistors. Also, in an embodiment, the semiconductor devices have a three-dimensional architecture, such as a trigate device, an independently accessed double gate device, a FIN-FET device, a nanowire device, or a nanoribbon device. One or more embodiments may be particularly useful for fabricating semiconductor devices at a 10 nanometer (10 nm) or smaller technology node.

In an embodiment, as is also used throughout the present description, lithographic operations are performed using 193 nm immersion lithography (i193), extreme ultra-violet (EUV) and/or electron beam direct write (EBDW) lithography, or the like. A positive tone or a negative tone resist may be used. In one embodiment, a lithographic mask is a trilayer mask composed of a topographic masking portion, an anti-reflective coating (ARC) layer, and a photoresist layer. In a particular such embodiment, the topographic masking portion is a carbon hardmask (CHM) layer and the anti-reflective coating layer is a silicon ARC layer.

Embodiments disclosed herein may be used to manufacture a wide variety of different types of integrated circuits and/or microelectronic devices. Examples of such integrated circuits include, but are not limited to, processors, chipset components, graphics processors, digital signal processors, micro-controllers, and the like. In other embodiments, semiconductor memory may be manufactured. Moreover, the integrated circuits or other microelectronic devices may be used in a wide variety of electronic devices known in the art. For example, in computer systems (e.g., desktop, laptop, server), cellular phones, personal electronics, etc. The integrated circuits may be coupled with a bus and other components in the systems. For example, a processor may be coupled by one or more buses to a memory, a chipset, etc. Each of the processor, the memory, and the chipset, may potentially be manufactured using the approaches disclosed herein.

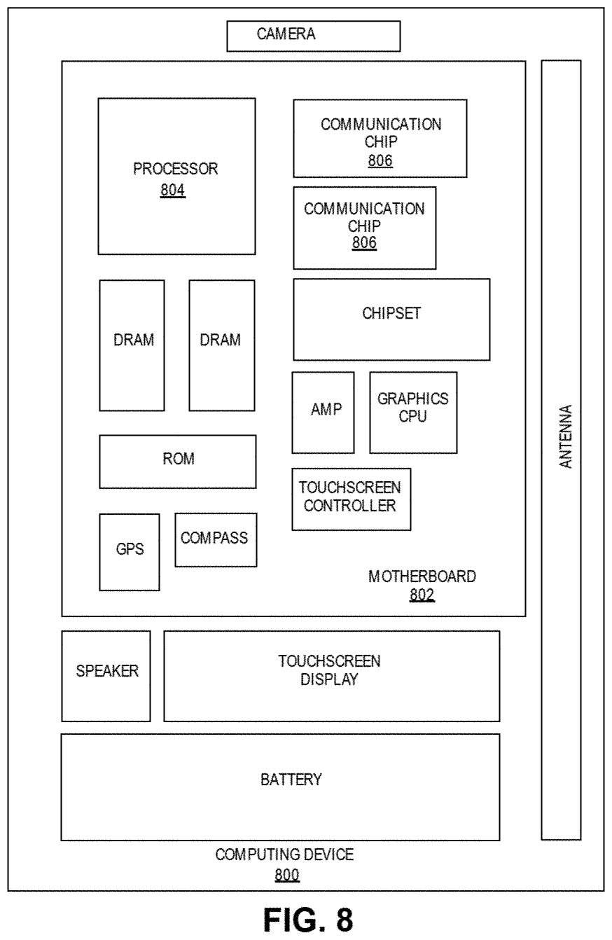

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

Depending on its applications, computing device 800 may include other components that may or may not be physically and electrically coupled to the board 802. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor includes one or more structures fabricated to include a metal layer formed using a beam of low energy atoms, in accordance with implementations of embodiments of the disclosure. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of embodiments of the disclosure, the integrated circuit die of the communication chip includes one or more structures fabricated to include a metal layer formed using a beam of low energy atoms, in accordance with implementations of embodiments of the disclosure.

In further implementations, another component housed within the computing device 800 may contain an integrated circuit die that includes one or more structures fabricated to include a metal layer formed using a beam of low energy atoms, in accordance with implementations of embodiments of the disclosure.

In various implementations, the computing device 800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

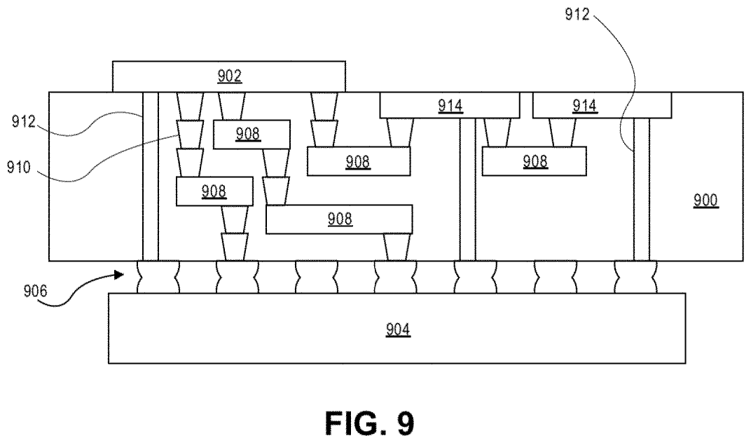

FIG. 9 illustrates an interposer 900 that includes one or more embodiments of the disclosure. The interposer 900 is an intervening substrate used to bridge a first substrate 902 to a second substrate 904. The first substrate 902 may be, for instance, an integrated circuit die. The second substrate 904 may be, for instance, a memory module, a computer motherboard, or another integrated circuit die. Generally, the purpose of an interposer 900 is to spread a connection to a wider pitch or to reroute a connection to a different connection. For example, an interposer 900 may couple an integrated circuit die to a ball grid array (BGA) 906 that can subsequently be coupled to the second substrate 904. In some embodiments, the first and second substrates 902/904 are attached to opposing sides of the interposer 900. In other embodiments, the first and second substrates 902/904 are attached to the same side of the interposer 900. And in further embodiments, three or more substrates are interconnected by way of the interposer 900.

The interposer 900 may be formed of an epoxy resin, a fiberglass-reinforced epoxy resin, a ceramic material, or a polymer material such as polyimide. In further implementations, the interposer 900 may be formed of alternate rigid or flexible materials that may include the same materials described above for use in a semiconductor substrate, such as silicon, germanium, and other group III-V and group IV materials.

The interposer 900 may include metal interconnects 908 and vias 910, including but not limited to through-silicon vias (TSVs) 912. The interposer 900 may further include embedded devices 914, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 900. In accordance with embodiments of the disclosure, apparatuses or processes disclosed herein may be used in the fabrication of interposer 900.

Thus, embodiments described herein include systems and approaches for fabricating an integrated circuit structure including a metal layer formed using a beam of low energy atoms.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example embodiment 1: A system for fabricating an integrated circuit structure includes a sample holder for supporting a substrate facing down, the substrate having a feature thereon. The system also includes a source for providing a beam of low energy metal atoms to form a metal layer on the feature of the substrate. The system also includes a source of gas atoms with an energy in the range of 50-800 eV, the source of gas atoms for removing weakly held metal atoms from the feature.

Example embodiment 2: The system of example embodiment 1, wherein the source for providing the beam of low energy metal atoms and the source of gas atoms are operated simultaneously.

Example embodiment 3: The system of example embodiment 1, wherein the source for providing the beam of low energy metal atoms and the source of gas atoms are operated alternately.

Example embodiment 4: The system of example embodiment 1, 2 or 3, wherein the beam of low energy metal atoms has an energy of approximately 0.1 eV, wherein the beam of low energy metal atoms has a linear shape, and wherein a metal source of the metal layer is continuously supplied to the source for providing the beam of low energy metal atoms.

Example embodiment 5: The system of example embodiment 1, 2, 3 or 4, wherein the feature is a source/drain contact trench exposing a semiconductor source/drain structure, and wherein the metal layer is a conductive contact layer for the semiconductor source/drain structure.

Example embodiment 6: The system of example embodiment 1, 2, 3 or 4, wherein the feature is a conductive line of a back end-of-line (BEOL) metallization layer, and wherein the metal layer is barrier layer for a conductive line.

Example embodiment 7: The system of example embodiment 1, 2, 3 or 4, wherein the feature is a gate trench of a semiconductor device, and wherein the metal layer is a workfunction layer of a metal gate electrode of the semiconductor device.

Example embodiment 8: A method of fabricating an integrated circuit structure includes providing a substrate, the substrate having a feature thereon. The method also includes forming a metal layer on the feature of the substrate using a beam of low energy metal atoms. The method also includes removing weakly held metal atoms from the feature using a source of gas atoms.

Example embodiment 9: The method of example embodiment 8, wherein using the beam of low energy metal atoms and using the source of gas atoms are operated simultaneously.

Example embodiment 10: The method of example embodiment 8, wherein using the beam of low energy metal atoms and using the source of gas atoms are operated alternately.

Example embodiment 11: The method of example embodiment 8, 9 or 10, wherein the beam of low energy metal atoms has an energy of approximately 0.1 eV.

Example embodiment 12: The method of example embodiment 8, 9, 10 or 11, wherein the feature is a source/drain contact trench exposing a semiconductor source/drain structure, and wherein the metal layer is a conductive contact layer for the semiconductor source/drain structure.

Example embodiment 13: The method of example embodiment 8, 9, 10 or 11, wherein the feature is a conductive line of a back end-of-line (BEOL) metallization layer, and wherein the metal layer is barrier layer for a conductive line.

Example embodiment 14: The method of example embodiment 8, 9, 10 or 11, wherein the feature is a gate trench of a semiconductor device, and wherein the metal layer is a workfunction layer of a metal gate electrode of the semiconductor device.

Example embodiment 15: A computing device includes a board and a component coupled to the board. The component includes an integrated circuit structure. The integrated circuit structure is fabricated according to a method. The method includes providing a substrate, the substrate having a feature thereon, forming a metal layer on the feature of the substrate using a beam of low energy metal atoms, and removing weakly held metal atoms from the feature using a source of gas atoms.

Example embodiment 16: The computing device of example embodiment 15, further including a memory coupled to the board.

Example embodiment 17: The computing device of example embodiment 15 or 16, further including a communication chip coupled to the board.

Example embodiment 18: The computing device of example embodiment 15, 16 or 17, further including a camera coupled to the board.

Example embodiment 19: The computing device of example embodiment 15, 16 , 17 or 18, further including a battery coupled to the board.

Example embodiment 20: The computing device of example embodiment 15, 16, 17, 18 or 19, further including an antenna coupled to the board.

Example embodiment 21: The computing device of example embodiment 15, 16, 17, 18, 19 or 20, wherein the component is a packaged integrated circuit die.

What is claimed is:

1. A system for fabricating an integrated circuit structure, the system comprising:
a sample holder for supporting a substrate wafer facing down, the substrate having a feature thereon;
a source for providing a beam of low energy metal atoms to form a metal layer on the feature of the substrate;
a source of gas atoms with energy 50-800 eV, the source of gas atoms for removing weakly held metal atoms from the feature.

2. The system of claim 1, wherein the source for providing the beam of low energy metal atoms and the source of gas atoms are operated simultaneously.

3. The system of claim 1, wherein the source for providing the beam of low energy metal atoms and the source of gas atoms are operated alternately.

4. The system of claim 1, wherein the beam of low energy metal atoms has an energy of approximately 0.1 eV, wherein the beam of low energy metal atoms has a linear shape, and wherein a metal source of the metal layer is continuously supplied to the source for providing the beam of low energy metal atoms.

5. The system of claim 1, wherein the feature is a source/drain contact trench exposing a semiconductor source/drain structure, and wherein the metal layer is a conductive contact layer for the semiconductor source/drain structure.

6. The system of claim 1, wherein the feature is a conductive line of a back end-of-line (BEOL) metallization layer, and wherein the metal layer is barrier layer for a conductive line.

7. The system of claim 1, wherein the feature is a gate trench of a semiconductor device, and wherein the metal layer is a workfunction layer of a metal gate electrode of the semiconductor device.

8. A method of fabricating an integrated circuit structure, the method comprising:
providing a substrate, the substrate having a feature thereon;
forming a metal layer on the feature of the substrate using a beam of low energy metal atoms; and
removing weakly held metal atoms from the feature using a source of gas atoms.

9. The method of claim 8, wherein using the beam of low energy metal atoms and using the source of gas atoms are operated simultaneously.

10. The method of claim 8, wherein using the beam of low energy metal atoms and using the source of gas atoms are operated alternately.

11. The method of claim 8, wherein the beam of low energy metal atoms has an energy of approximately 0.1 eV.

12. The method of claim 8, wherein the feature is a source/drain contact trench exposing a semiconductor source/drain structure, and wherein the metal layer is a conductive contact layer for the semiconductor source/drain structure.

13. The method of claim 8, wherein the feature is a conductive line of a back end-of-line (BEOL) metallization layer, and wherein the metal layer is barrier layer for a conductive line.

14. The method of claim 8, wherein the feature is a gate trench of a semiconductor device, and wherein the metal layer is a workfunction layer of a metal gate electrode of the semiconductor device.

15. A computing device, comprising:
a board; and
a component coupled to the board, the component including an integrated circuit structure fabricated according to a method, the method comprising:
providing a substrate, the substrate having a feature thereon;
forming a metal layer on the feature of the substrate using a beam of low energy metal atoms; and
removing weakly held metal atoms from the feature using a source of gas atoms.

16. The computing device of claim 15, further comprising:
a memory coupled to the board.

17. The computing device of claim 15, further comprising:
a communication chip coupled to the board.

18. The computing device of claim 15, further comprising:
a camera coupled to the board.

19. The computing device of claim 15, further comprising:
a battery coupled to the board.

20. The computing device of claim 15, further comprising:
an antenna coupled to the board.

21. The computing device of claim 15, wherein the component is a packaged integrated circuit die.
